(19) United States
(12) Patent Application Publication
(10) Pub. No.: US 2019/0157047 A1
(43) Pub. Date: May 23, 2019

(54) PLASMA SPRAY COATING ENHANCEMENT USING GRADUATED PARTICLE FEED RATE

(71) Applicant: Applied Materials, Inc., Santa Clara, CA (US)

(72) Inventors: Yikai Chen, Santa Clara, CA (US); Shyh-Nung Steve Lin, San Jose, CA (US)

(21) Appl. No.: 16/192,610

(22) Filed: Nov. 15, 2018

Related U.S. Application Data
(60) Provisional application No. 62/590,024, filed on Nov. 22, 2017.

(51) Int. Cl. H01J 37/32; C23C 4/134; C23C 4/11; C23C 4/06

(52) U.S. Cl. CPC H01J 37/32495; H01J 37/32467; C23C 4/06; C23C 4/11; C23C 4/134

(57) ABSTRACT

A method for forming a ceramic coating on an article includes placing the article into a chamber or spray cell of a plasma spraying system. A first ceramic powder is then fed into the plasma spraying system at a first powder feed rate, and a first layer of a plasma resistant ceramic coating is deposited onto at least one surface of the article in a plasma spray process by the plasma spray system. The powder feed rate is adjusted to a second powder feed rate, and a second layer of the plasma resistant ceramic coating is deposited onto the at least one surface of the article in the plasma spray process by the plasma spray system.

### RELATED APPLICATIONS

This patent application claims the benefit under 35 U.S.C. § 119(e) of U.S. Provisional Application No. 62/590,024, filed Nov. 22, 2017.

### TECHNICAL FIELD

Embodiments of the present disclosure relate, in general, to ceramic coated articles and to a process for plasma spraying a ceramic coating onto chamber components.

### BACKGROUND

In the semiconductor industry, devices are fabricated by a number of manufacturing processes producing structures of an ever-decreasing size. Some manufacturing processes such as plasma etch and plasma clean processes expose a substrate to a high-speed stream of plasma to etch or clean the substrate. The plasma may be highly corrosive, and may corrode processing chambers and other surfaces that are exposed to the plasma. This corrosion may generate particles, which frequently contaminate the substrate that is being processed, contributing to device defects.

As device geometries shrink, susceptibility to defects increases and particle contaminant requirements become more stringent. Accordingly, as device geometries shrink, allowable levels of particle contamination may be reduced. To minimize particle contamination introduced by plasma etch and/or plasma clean processes, chamber materials have been developed that are resistant to plasmas. Different materials provide different material properties, such as plasma resistance, rigidity, flexural strength, thermal shock resistance, and so on. Also, different materials have different material costs. Accordingly, some materials have superior plasma resistance, other materials have lower costs, and still other materials have superior flexural strength and/or thermal shock resistance.

### SUMMARY

In one embodiment, a method of plasma spraying comprises feeding a first ceramic powder into a plasma spraying system at a first powder feed rate. The method further comprises depositing a first layer of a ceramic coating on at least one surface of an article in a plasma spray process by the plasma spray system using the first powder feed rate. The method further comprises feeding at least one of the first ceramic powder or a second ceramic powder into the plasma spraying system at a second powder feed rate that is lower than the first powder feed rate. The method further comprises depositing a second layer of the ceramic coating on the at least one surface of the article in the plasma spray process by the plasma spray system using the second powder feed rate.

In one embodiment, a method of plasma spraying comprises feeding a first ceramic powder into a plasma spraying system at a first powder feed rate, wherein the first ceramic powder has a first average particle size. The method further comprises depositing a first layer of a ceramic coating on at least one surface of an article in a plasma spray process by the plasma spray system using the first ceramic powder. The method further comprises feeding a second ceramic powder into the plasma spraying system at the first powder feed rate or at a second powder feed rate that is lower than the first powder feed rate, wherein the second ceramic powder has a second average particle size that is lower than the first average particle size. The method further comprises depositing a second layer of the ceramic coating on the at least one surface of the article in the plasma spray process by the plasma spray system using the second ceramic powder.

In one embodiment, a chamber component for a processing chamber has a ceramic coating on at least one surface, the ceramic coating having been formed by a process comprising feeding a first ceramic powder into a plasma spraying system at a first powder feed rate. The process of forming the ceramic coating further comprises depositing a first layer of the ceramic coating on the at least one surface of the chamber component in a plasma spray process by the plasma spray system using the first powder feed rate. The process of forming the ceramic coating further comprises feeding at least one of the first ceramic powder or a second ceramic powder into the plasma spraying system at a second powder feed rate that is lower than the first powder feed rate. The process of forming the ceramic coating further comprises depositing a second layer of the ceramic coating on the at least one surface of the chamber component in the plasma spray process by the plasma spray system using the second powder feed rate.

### BRIEF DESCRIPTION OF THE DRAWINGS

The present disclosure is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIG. 1 depicts a sectional view of one embodiment of a processing chamber.

FIG. 2 illustrates an exemplary architecture of a manufacturing system, in accordance with one embodiment of the present disclosure.

FIG. 3 depicts a schematic of a plasma spray deposition system, in accordance with one embodiment of the present disclosure.

FIG. 4 depicts particles in a ceramic powder, in accordance with one embodiment of the present disclosure.

FIG. 5 illustrates one embodiment of a process for forming a plasma sprayed ceramic coating over a chamber component.

### DETAILED DESCRIPTION OF EMBODIMENTS

Embodiments of the disclosure are directed to a process for coating an article with a ceramic coating using at least one of a graduated powder feed rate or a sequence of ceramic powders having decreasing average particle size. In one embodiment, a plasma spray process is performed using an initial powder feed rate until a target thickness is reached and/or until a threshold amount of time has passed. The initial powder feed rate may then be reduced, and the plasma spray process may continue at the reduced powder feed rate until a new target thickness is reached and/or until a second threshold amount of time has passed. The initial powder feed rate may then be further reduced one or more additional times during the plasma spray process until a final target thickness for the ceramic coating is reached.

In one embodiment, a plasma spray process is performed using a first ceramic powder having a first average particle size until a target thickness is reached and/or until a threshold amount of time has passed. A second ceramic powder having a smaller second average particle size may then be used to continue the plasma spray process until a second target thickness is reached and/or until a second threshold amount of time has passed. One or more additional ceramic powders may be used to further deposit the ceramic coating until a final target thickness for the ceramic coating is reached, where each successive ceramic powder has a smaller average particle size than a previous ceramic powder.

In one embodiment, a plasma spray process is performed using a first ceramic powder having a first average particle size and a first powder feed rate until a target thickness is reached and/or until a threshold amount of time has passed. A second ceramic powder having a smaller second average particle size and a lower second powder feed rate may then be used to continue the plasma spray process until a second target thickness is reached and/or until a second threshold amount of time has passed. One or more additional ceramic powders and accompanying lower powder feed rates may be used to further deposit the ceramic coating until a final target thickness for the ceramic coating is reached, where each successive ceramic powder has a smaller average particle size than a previous ceramic powder.

The processes disclosed herein provide improved particle contamination performance for chamber components as compared to standard plasma spray processes. Additionally, the processes disclosed herein provide improved surface morphology for a plasma sprayed coating. The improved surface morphology may include a lower average surface roughness (Ra) as well as a lower porosity at the surface of the ceramic coating. Additionally, a plasma sprayed coating typically has a greater density and lower porosity near a bottom of the coating and a lower density and higher porosity near a top of the coating. This is because the lower portion of the ceramic coating is bombarded by a stream of additional particles (e.g., molten particles), which serves to densify the lower portion of the ceramic coating and to transfer additional heat to the lower portion of the ceramic coating. However, the upper portion of the ceramic coating formed by the plasma spray process is not subject to bombardment by further particles and/or is subject to bombardment to only a small amount of further particles. Accordingly, less heat is transferred to the upper portion of the ceramic coating. As a result, a typical plasma sprayed ceramic coating has a porosity gradient, with a lower porosity at a bottom of the ceramic coating and a lower porosity at a surface of the ceramic coating.

A plasma sprayed coating deposited by a standard plasma spray process generally has a porosity of about 3-10% and an average surface roughness (Ra) of about 150-350 micro-inches. Additionally, the surface of a plasma sprayed coating generally has a high number of unmelted and/or partially melted surface nodules and/or a high number of loosely bonded particles. Such surface nodules, loosely bonded particles and relatively high roughness may be a source of particle contamination during subsequent processing.

In some instances, heat treatments have been performed after a plasma spray process in attempts to improve the surface quality of the deposited ceramic coating. However, heat treatments are generally performed by equipment other than the plasma spray system used to deposit the plasma resistant ceramic coating. Accordingly, a lead time is increased for these other heat treatment processes. Additionally, transport of the article to the equipment for the other heat treatment processes increases a risk of contamination. In addition, laser melting may create vertical and horizontal cracks in the ceramic coating. Spark plasma sintering is limited in application to small sample sizes. Furnace heat treatment is not applicable for many types of substrates, such as for some metal substrates, electrostatic chucks, and so on. Embodiments described herein achieve reduced particle contamination without any subsequent heat treatments.

One type of heat treatment that has been performed is a plasma flame heat treatment. Such a plasma flame heat treatment may improve the surface of the plasma sprayed coating, but does not affect the underlying microstructure of the interior of the plasma sprayed coating. For example, standard plasma sprayed coatings have a graduated porosity, with a bottom portion of the plasma sprayed coating having a lower porosity and a higher density than an upper portion of the plasma sprayed coating. In contrast, embodiments described herein improve both the surface of the plasma sprayed coating as well as the interior microstructure of the plasma sprayed coating by reducing using graduated powder feed rates, where a higher powder feed rate is used initially, and a reduced powder feed rate us used subsequently. In one embodiment, the plasma sprayed coating has an approximately uniform porosity and density throughout the plasma sprayed coating due at least in part to the changes in the powder feed rate during the plasma spray deposition process.

When the terms “about” and “approximately” are used herein, these are intended to mean that the nominal value presented is precise within ±10%. The articles described herein may be structures that are exposed to plasma, such as chamber components for a plasma etcher (also known as a plasma etch reactor) or other processing chamber. For example, the articles may be chamber liners, walls, bases, gas distribution plates, shower heads, substrate holding frames, electrostatic chucks, rings, lids, nozzles, faceplates, selectivity modulation devices (SMDs) etc. of processing chamber such as a processing chamber for a plasma etcher, a plasma cleaner, or other type of manufacturing machine.

Moreover, embodiments are described herein with reference to ceramic coated chamber components and other articles that may cause reduced particle contamination when used in a process chamber for plasma rich processes. However, it should be understood that the ceramic coated articles discussed herein may also provide reduced particle contamination when used in process chambers for other processes such as non-plasma etchers, non-plasma cleaners, chemical vapor deposition (CVD) chamber, physical vapor deposition (PVD) chamber, and so forth. Moreover, some embodiments are described with reference to specific plasma resistant ceramics. However, it should be understood that embodiments equally apply to other plasma resistant ceramics than those discussed herein.

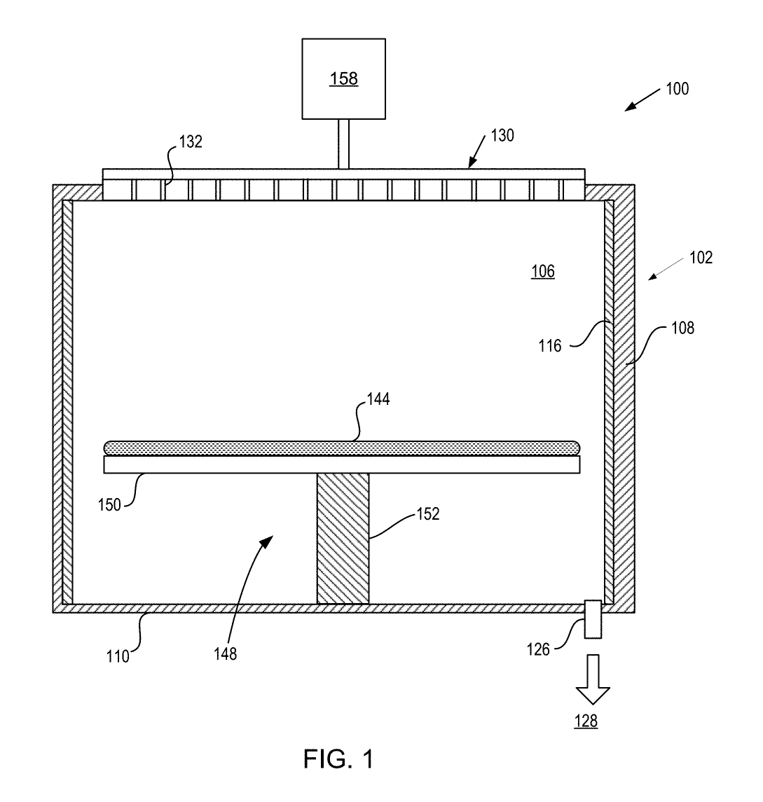

FIG. 1 is a sectional view of a processing chamber 100 (e.g., a semiconductor processing chamber) having one or more chamber components that are coated with a ceramic coating in accordance with embodiments of the present disclosure. The ceramic coating described in embodiments is a plasma-sprayed coating that has been deposited using the plasma spraying process described with reference to one or more embodiments. The processing chamber 100 may be used for processes in which a corrosive plasma environment is provided. For example, the processing chamber 100 may be a chamber for a plasma etch reactor (also known as a plasma etcher), a plasma cleaner, plasma enhanced chemical vapor deposition (CVD) or atomic layer deposition (ALD) reactors and so forth.

In one embodiment, the processing chamber 100 includes a chamber body 102 and a showerhead 130 that encloses an interior volume 106. The showerhead 130 may include a showerhead base and a showerhead gas distribution plate. Alternatively, the showerhead 130 may be replaced by a lid and a nozzle in some embodiments, or by multiple pie shaped showerhead compartments and plasma generation units in other embodiments. The chamber body 102 may be fabricated from aluminum, stainless steel or other suitable material such as titanium (Ti). The chamber body 102 generally includes sidewalls 108 and a bottom 110.

An outer liner 116 may be disposed adjacent the sidewalls 108 to protect the chamber body 102. In one embodiment, the outer liner 116 is fabricated from aluminum oxide.

An exhaust port 126 may be defined in the chamber body 102, and may couple the interior volume 106 to a pump system 128. The pump system 128 may include one or more pumps and throttle valves utilized to evacuate and regulate the pressure of the interior volume 106 of the processing chamber 100.

A showerhead 130 may be supported on the sidewall 108 of the chamber body 102. Alternatively, a lid may be supported on the sidewall 108 of the chamber body. The lid may include a hole that into which a nozzle has been inserted. The showerhead 130 (or lid) may be opened to allow access to the interior volume 106 of the processing chamber 100, and may provide a seal for the processing chamber 100 while closed. A gas panel 158 may be coupled to the processing chamber 100 to provide process and/or cleaning gases to the interior volume 106 through the showerhead 130 or lid and nozzle. Showerhead 130 may be used for processing chambers used for dielectric etch (etching of dielectric materials). The showerhead 130 may include a gas distribution plate (GDP) and may have multiple gas delivery holes 132 throughout the GDP. The showerhead 130 may include the GDP bonded to an aluminum base or an anodized aluminum base. The GDP may be made from Si or SiC, or may be a ceramic such as Y₂O₃, Al₂O₃, Y₃Al₅O₁₂ (YAG), and so forth.

For processing chambers used for conductor etch (etching of conductive materials), a lid may be used rather than a showerhead. The lid may include a center nozzle that fits into a center hole of the lid. The lid may be a ceramic such as Al₂O₃, Y₂O₃, YAG, or a ceramic compound comprising Y₄Al₂O₉ and a solid-solution of Y₂O₃—ZrO₂. The nozzle may also be a ceramic, such as Y₂O₃, YAG, or the ceramic compound comprising Y₄Al₂O₉ and a solid-solution of Y₂O₃—ZrO₂.

Examples of processing gases that may be used to process substrates in the processing chamber 100 include halogen-containing gases, such as C₂F₆, SF₆, SiCl₄, HBr, NF₃, CF₄, CHF₃, CH₂F₃, F, NF₃, Cl₂, CCl₄, BCl₃ and SiF₄, among others, and other gases such as O₂, or N₂O. Examples of carrier gases include N₂, He, Ar, and other gases inert to process gases (e.g., non-reactive gases).

A substrate support assembly 148 is disposed in the interior volume 106 of the processing chamber 100 below the showerhead 130. The substrate support assembly 148 holds a substrate 144 during processing. A ring (e.g., a single ring) may cover a portion of the electrostatic chuck 150, and may protect the covered portion from exposure to plasma during processing. The ring may be silicon or quartz in one embodiment.

An inner liner may be coated on the periphery of the substrate support assembly 148. The inner liner may be a halogen-containing gas resist material such as those discussed with reference to the outer liner 116. In one embodiment, the inner liner may be fabricated from the same materials of the outer liner 116.

In one embodiment, the substrate support assembly 148 includes a pedestal 152 that supports an electrostatic chuck 150. The electrostatic chuck 150 further includes a thermally conductive base and an electrostatic puck bonded to the thermally conductive base by a bond, which may be a silicone bond in one embodiment. The thermally conductive base and/or electrostatic puck of the electrostatic chuck 150 may include one or more optional embedded heating elements, embedded thermal isolators and/or conduits to control a lateral temperature profile of the substrate support assembly 148. The electrostatic puck may further include multiple gas passages such as grooves, mesas and other surface features that may be formed in an upper surface of the electrostatic puck. The gas passages may be fluidly coupled to a source of a heat transfer (or backside) gas such as He via holes drilled in the electrostatic puck. In operation, the backside gas may be provided at controlled pressure into the gas passages to enhance the heat transfer between the electrostatic puck and a supported substrate 144. The electrostatic chuck 150 may include at least one clamping electrode controlled by a chucking power source.

Any of the aforementioned chamber components of processing chamber 100 may include a ceramic coating that was deposited in accordance with embodiments described herein. Examples of chamber components that may include a plasma resistant ceramic coating include the substrate support assembly 148, electrostatic chuck (ESC) 150, a ring (e.g., a process kit ring or single ring), a chamber wall, a base, a gas distribution plate, the showerhead 130, the outer liner 116, an inner liner, a liner kit, a shield, a plasma screen, a flow equalizer, a cooling base, a chamber viewport, a chamber lid, a nozzle, process kit rings, a faceplate, a selectivity modulation device (SMD), and so on.

The plasma resistant ceramic coating, may be a rare earth oxide coating, a rare earth fluoride coating, a rare earth oxy-fluoride coating or other ceramic coating deposited by an atmospheric pressure plasma spraying (APPS) process or a low pressure plasma spray (LPPS) process. The plasma resistant coating may include Y₂O₃ and Y₂O₃ based ceramics, Y₃Al₅O₁₂ (YAG), Al₂O₃ (alumina), Y₄Al₂O₉ (YAM), YF₃, SiC (silicon carbide), ErAlO₃, GdAlO₃, NdAlO₃, YAlO₃, Si₃N₄ (silicon nitride), AlN (aluminum nitride), TiO₂ (titania), ZrO₂ (zirconia), TiC (titanium carbide), ZrC (zirconium carbide), TiN (titanium nitride), Y₂O₃ stabilized ZrO₂ (YSZ), Er₂O₃ and Er₂O₃ based ceramics, Gd₂O₃ and Gd₂O₃ based ceramics, Er₃Al₅O₁₂ (EAG), Gd₃Al₅O₁₂ (GAG), Nd₂O₃ and Nd₂O₃ based ceramics, a ceramic compound comprising Y₂O₃ and YF₃ (e.g., Y—O—F), a ceramic compound comprising Y₄Al₂O₉ and a solid-solution of Y₂O₃—ZrO₂, a ceramic compound comprising Y₂O₃, Er₂O₃, ZrO₂, Gd₂O₃ and SiO₂, or a combination of any of the above.

The plasma resistant coating may also be based on a solid solution formed by any of the aforementioned ceramics. The plasma resistant ceramic coating may also be a multiphase material that includes a solid solution of one or more of the aforementioned materials and one or more additional phase.

With reference to the solid-solution of Y₂O₃—ZrO₂, the plasma sprayed ceramic coating may include Y₂O₃ at a concentration of 10-90 molar ratio (mol %) and ZrO₂ at a concentration of 10-90 mol %. In some examples, the solid-solution of Y₂O₃—ZrO₂ may include 10-20 mol % Y₂O₃ and 80-90 mol % ZrO₂, may include 20-30 mol % Y₂O₃ and 70-80 mol % ZrO₂, may include 30-40 mol % Y₂O₃ and 60-70 mol % ZrO₂, may include 40-50 mol % Y₂O₃ and 50-60 mol % ZrO₂, may include 60-70 mol % Y₂O₃ and 30-40 mol % ZrO₂, may include 70-80 mol % Y₂O₃ and 20-30 mol % ZrO₂, may include 80-90 mol % Y₂O₃ and 10-20 mol % ZrO₂, and so on.

With reference to the ceramic compound comprising Y₄Al₂O₉ and a solid-solution of Y₂O₃—ZrO₂, in one embodiment the ceramic compound includes 62.93 molar ratio (mol %) Y₂O₃, 23.23 mol % ZrO₂ and 13.94 mol % Al₂O₃. In another embodiment, the ceramic compound can include Y₂O₃ in a range of 50-75 mol %, ZrO₂ in a range of 10-30 mol % and Al₂O₃ in a range of 10-30 mol %. In another embodiment, the ceramic compound can include Y₂O₃ in a range of 40-100 mol %, ZrO₂ in a range of 0.1-60 mol % and Al₂O₃ in a range of 0.1-10 mol %. In another embodiment, the ceramic compound can include Y₂O₃ in a range of 40-60 mol %, ZrO₂ in a range of 35-50 mol % and Al₂O₃ in a range of 10-20 mol %. In another embodiment, the ceramic compound can include Y₂O₃ in a range of 40-50 mol %, ZrO₂ in a range of 20-40 mol % and Al₂O₃ in a range of 20-40 mol %. In another embodiment, the ceramic compound can include Y₂O₃ in a range of 80-90 mol %, ZrO₂ in a range of 0.1-20 mol % and Al₂O₃ in a range of 10-20 mol %. In another embodiment, the ceramic compound can include Y₂O₃ in a range of 60-80 mol %, ZrO₂ in a range of 0.1-10 mol % and Al₂O₃ in a range of 20-40 mol %. In another embodiment, the ceramic compound can include Y₂O₃ in a range of 40-60 mol %, ZrO₂ in a range of 0.1-20 mol % and Al₂O₃ in a range of 30-40 mol %. In other embodiments, other distributions may also be used for the ceramic compound.

In one embodiment, the plasma sprayed ceramic coating includes or consists of a ceramic compound that includes a combination of Y₂O₃, ZrO₂, Er₂O₃, Gd₂O₃ and SiO₂. In one embodiment, the ceramic compound can include Y₂O₃ in a range of 40-45 mol %, ZrO₂ in a range of 0-10 mol %, Er2O3 in a range of 35-40 mol %, Gd₂O₃ in a range of 5-10 mol % and SiO2 in a range of 5-15 mol %. In a first example, the alternative ceramic compound includes 40 mol % Y₂O₃, 5 mol % ZrO₂, 35 mol % Er₂O₃, 5 mol % Gd₂O₃ and 15 mol % SiO₂. In a second example, the alternative ceramic compound includes 45 mol % Y₂O₃, 5 mol % ZrO₂, 35 mol % Er₂O₃, 10 mol % Gd₂O₃ and 5 mol % SiO₂. In a third example, the alternative ceramic compound includes 40 mol % Y₂O₃, 5 mol % ZrO₂, 40 mol % Er₂O₃, 7 mol % Gd₂O₃ and 8 mol % SiO₂.

With regards to the plasma sprayed ceramic coating comprising a combination of Y₂O₃ and YF₃, the coating may be a Y—O—F coating that has a single Y—O—F phase or multiple different Y—O—F phases. Some possible Y—O—F phases that the Y—O—F coating may have are YOF ht, YOF rt, YOF tet, Y₂OF₄ (e.g., Y₂OF₄ ht-hp), Y₃O₂F₅ (e.g., Y₃O₂F₅ ht-hp), YO_{0.4}F₂₂ (e.g., YO_{0.4}F₂₂ht-hp), Y₅O₄F₇, Y₆O₅F₈, Y₇O₆F₉, and Y₁₇O₁₄F₂₃. In some embodiments, the plasma sprayed coating is a Y—Zr—O—F coating.

Any of the aforementioned plasma resistant ceramic coatings may include trace amounts of other materials such as ZrO₂, Al₂O₃, SiO₂, B₂O₃, Er₂O₃, Nd₂O₃, Nb₂O₅, CeO₂, Sm₂O₃, Yb₂O₃, or other oxides. The ceramic coating allows for longer working lifetimes due to the plasma resistance of the ceramic coating and decreased on-wafer or substrate contamination. Beneficially, in some embodiments the ceramic coating may be stripped and re-coated without affecting the dimensions of the substrates that are coated.

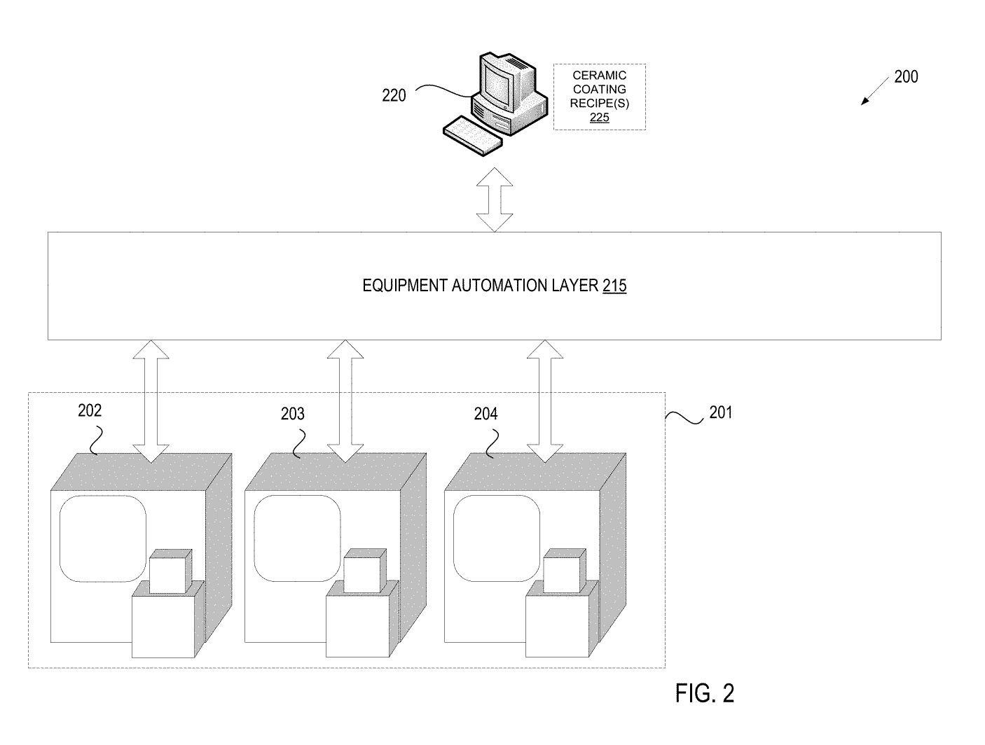

FIG. 2 illustrates an example architecture of a manufacturing system 200. The manufacturing system 200 may be a ceramics manufacturing system. In one embodiment, the manufacturing system 200 includes manufacturing machines 201 (also referred to as processing equipment) connected to an equipment automation layer 215. The manufacturing machines 201 may include a bead blaster 202, one or more wet cleaners 203, and/or a plasma spraying system 204. The manufacturing system 200 may further include one or more computing device 220 connected to the equipment automation layer 215. In alternative embodiments, the manufacturing system 200 may include more or fewer components. For example, the manufacturing system 200 may include manually operated (e.g., off-line) manufacturing machines 201 without the equipment automation layer 215 or the computing device 220.

Bead blaster 202 is a machine configured to roughen the surface of articles such as articles. Bead blaster 202 may be a bead blasting cabinet, a hand held bead blaster, or other type of bead blaster. Bead blaster 202 may roughen a substrate by bombarding the substrate with beads or particles. In one embodiment, bead blaster 202 fires ceramic beads or particles at the substrate. The roughness achieved by the bead blaster 202 may be based on a force used to fire the beads, bead materials, bead sizes, distance of the bead blaster from the substrate, processing duration, and so forth. In one embodiment, the bead blaster uses a range of bead sizes to roughen the ceramic article. Bead blaster 202 may roughen the surface of an article such as a chamber component for a processing chamber prior to performing a plasma spray process to increase adhesion strength of the ceramic coating to the article.

In alternative embodiments, other types of surface rougheners than a bead blaster 202 may be used. For example, a motorized abrasive pad may be used to roughen the surface of ceramic substrates. A sander may rotate or vibrate the abrasive pad while the abrasive pad is pressed against a surface of the article. A roughness achieved by the abrasive pad may depend on an applied pressure, on a vibration or rotation rate and/or on a roughness of the abrasive pad.

Wet cleaners 203 are cleaning apparatuses that clean articles (e.g., articles) using a wet clean process. Wet cleaners 203 include wet baths filled with liquids, in which the substrate is immersed to clean the substrate. Wet cleaners 203 may agitate the wet bath using ultrasonic waves during cleaning to improve a cleaning efficacy. This is referred to herein as sonicating the wet bath.

In other embodiments, alternative types of cleaners such as dry cleaners may be used to clean the articles. Dry cleaners may clean articles by applying heat, by applying gas, by applying plasma, and so forth.

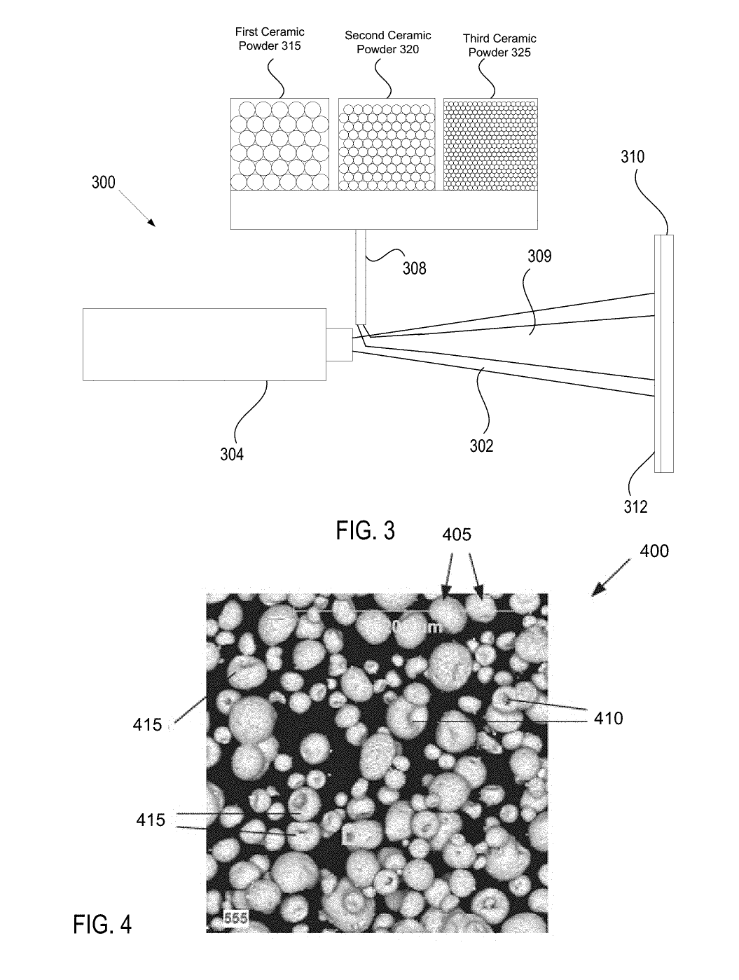

Plasma spraying system 204 is a machine configured to plasma spray a ceramic coating to the surface of a substrate. In one embodiment, plasma spraying system 204 is an atmospheric pressure plasma spraying (APPS) system (also referred to as an air plasma spraying (APS) system). In another embodiment, plasma spraying system 204 is a low pressure plasma spraying (LPPS) system. Plasma spraying systems are discussed in greater detail with reference to FIG. 3.

The equipment automation layer 215 may interconnect some or all of the manufacturing machines 201 with computing devices 220, with other manufacturing machines, with metrology tools and/or other devices. The equipment automation layer 215 may include a network (e.g., a location area network (LAN)), routers, gateways, servers, data stores, and so on. Manufacturing machines 201 may connect to the equipment automation layer 215 via a SEMI Equipment Communications Standard/Generic Equipment Model (SECS/GEM) interface, via an Ethernet interface, and/or via other interfaces. In one embodiment, the equipment automation layer 215 enables process data (e.g., data collected by manufacturing machines 201 during a process run) to be stored in a data store (not shown). In an alternative embodiment, the computing device 220 connects directly to one or more of the manufacturing machines 201.

In one embodiment, some or all manufacturing machines 201 include a programmable controller that can load, store and execute process recipes. The programmable controller may control temperature settings, gas and/or vacuum settings, time settings, etc. of manufacturing machines 201. The programmable controller may include a main memory (e.g., read-only memory (ROM), flash memory, dynamic random access memory (DRAM), static random access memory (SRAM), etc.), and/or a secondary memory (e.g., a data storage device such as a disk drive). The main memory and/or secondary memory may store instructions for performing heat treatment processes described herein.

The programmable controller may also include a processing device coupled to the main memory and/or secondary memory (e.g., via a bus) to execute the instructions. The processing device may be a general-purpose processing device such as a microprocessor, central processing unit, or the like. The processing device may also be a special-purpose processing device such as an application specific integrated circuit (ASIC), a field programmable gate array (FPGA), a digital signal processor (DSP), network processor, or the like. In one embodiment, programmable controller is a programmable logic controller (PLC).

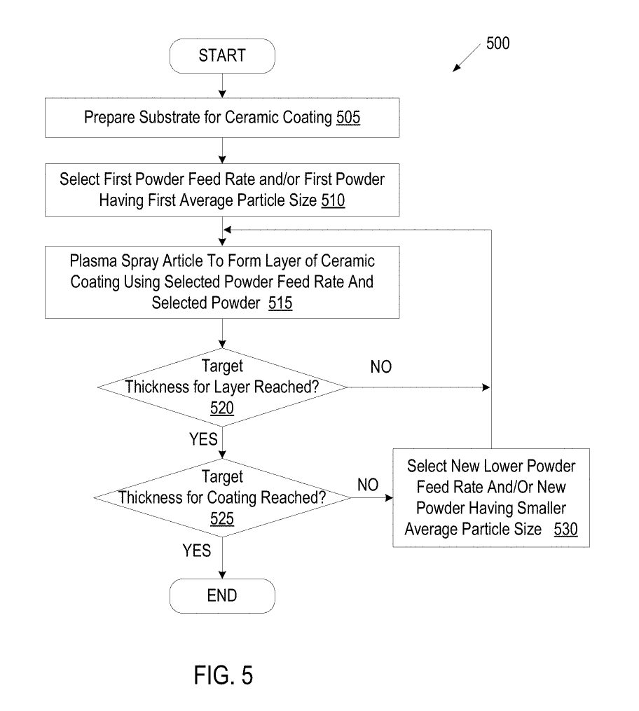

In one embodiment, the manufacturing machines 201 are programmed to execute recipes that will cause the manufacturing machines to roughen a substrate, clean a substrate and/or article, coat an article and/or machine (e.g., grind or polish) an article. In one embodiment, the manufacturing machines 201 are programmed to execute recipes that perform operations of a multi-step process for manufacturing a ceramic coated article, as described with reference to FIG. 5. The computing device 220 may store one or more ceramic coating recipes 225 that can be downloaded to the manufacturing machines 201 to cause the manufacturing machines 201 to manufacture ceramic coated articles in accordance with embodiments of the present disclosure.

FIG. 3 illustrates a plasma spray system 300 for plasma spraying a plasma resistant ceramic coating on a chamber component, or other article used in a corrosive system. The plasma spray system 300 is a type of thermal spray system. In one embodiment, the plasma spray system 300 is an APPS system. In one embodiment, the plasma spray system is an LPPS system. An APPS system operates at atmospheric pressure. An APPS system typically does not include any vacuum chamber, and may instead include an open chamber or room. An LPPS system is a plasma spray system that includes a vacuum chamber that can be pumped down to reduced pressure (e.g., to a vacuum of 1 Mbar, 10 Mbar, 35 Mbar, etc.). Ceramic coatings formed by an LPPS system are generally thinner and generally have a lower porosity than ceramic coatings formed by an APPS system.

In a plasma spray system, an arc is formed between two electrodes through which a gas is flowing. Examples of gas suitable for use in the plasma spray system 300 include, but are not limited to, Argon/Hydrogen, Argon/Helium or Argon/Oxygen. As the gas is heated by the arc, the gas expands and is accelerated through a shaped nozzle of a plasma torch 304, creating a high velocity plasma jet 302.

Powder 309 is injected into the plasma jet 302 by a powder delivery system 308. In the illustrated example, the powder delivery system 308 includes multiple different powder containers, where each of the powder containers contains a different ceramic powder. For example, as shown the powder delivery system 308 includes a first container with a first ceramic powder 315, a second container with a second ceramic powder 320 and a third container with a third ceramic powder 325. The first ceramic powder 315 may have a first average particle size that has a scale on the order of microns. The second ceramic powder 315 may have a second average particle size that is smaller than the first average particle size. The second particle size may be a micron-scale or nano-scale particle size. The third ceramic powder 325 may have a third particle size that is smaller than the second particle size. The third particle size may be a micron-scale or nano-scale particle size.

An intense temperature of the plasma jet 302 melts the powder 309 and propels the molten ceramic material towards an article 310. Upon impacting with the article 310, the molten powder flattens, rapidly solidifies, and forms a ceramic coating 312. The molten powder adheres to the article 310. The parameters that affect the thickness, density, and roughness of the ceramic coating 312 include type of powder, powder size distribution, powder feed rate, plasma gas composition, gas flow rate, energy input, pressure, and torch offset distance.

In one embodiment, the plasma spray system 300 is a conventional atmospheric pressure plasma spray (APPS) system that operates at atmospheric pressure to perform an APPS process. APPS systems produce ceramic coatings (e.g., oxide ceramic coatings) having a relatively high porosity. For example, APPS systems may produce ceramic coatings with a porosity of 3-10% in some embodiments. An APPS system may produce ceramic coatings having thicknesses of around 20 microns to several millimeters. For APPS, the ceramic coating bonds to the substrate mainly by mechanical bonding. Accordingly, in one embodiment the article 310 is roughened prior to forming the plasma sprayed ceramic coating 312.

The powder delivery system 308 may be operated to deliver a selected ceramic powder at a particular phase of a deposition process in some embodiments. For example, the first ceramic powder 315 may initially be fed into the plasma jet 302 until a first target thickness is reached, the second ceramic powder 320 may subsequently be fed into the plasma jet 302 until a second target thickness is reached, and the third ceramic powder 325 may be fed into the plasma jet 302 until a third target thickness is reached.

Alternatively, or additionally, the powder delivery system 308 may be adjusted to deliver a ceramic powder (e.g., one of first ceramic powder 315, second ceramic powder 320 or third ceramic powder 325) at a first powder feed rate during a first phase of a deposition process and to deliver the ceramic powder at a second lower powder feed rate during a second phase of the deposition process. The deposition process may additionally include one or more additional phases, where a progressively lower powder feed rate is used at each subsequent phase of the deposition process.

Some example values of deposition parameters for the plasma spray system 300 used in embodiments are provided below in Table 1. These parameters may include, but are not limited to, power of plasma, gun current, gun voltage, initial powder feed rate, gun stand-off distance, and gas flow rate. The powder feed rate may be about 10-200 grams per minute during a first phase of the deposition process. In one embodiment, the initial powder feed rate is 30-40 g/min. During a second phase of the deposition process the powder feed rate may be reduced to anywhere from about 10-90% of the initial powder feed rate. In various embodiments, the powder feed rate may be reduced to 10%, 15%, 20%, 25%, 30%, 35%, 40%, 45%, 50%, 55%, 60%, 65%, 70%, 75%, 80%, 85%, or 90% of the initial powder feed rate. There may also be further phases of the deposition process. If there are subsequent phases of the deposition process, in the subsequent phases of the deposition process the powder feed rate may be reduced further to a lower percentage of the initial powder feed rate. For example, at the second phase the powder feed rate may be reduced to 80% of the initial powder feed rate, at a third phase the powder feed rate may be reduced to 75% of the initial powder feed rate, and during a fourth phase the powder feed rate may be reduced to 50% of the initial powder feed rate. Any other number of phases greater than two may be utilized, and the powder feed rate may be lowered to any reduced percentage of the original powder feed rate during the subsequent phases, where each phase has a lower powder feed rate than the previous phase.

TABLE 1
Plasma Spray Input Parameters

| | | Coating |
|---|---|---|
| Input Parameter | Unit | Range |
| Power of Plasma | kW | 9-300 |
| Gun Current | A | 100-2000 |
| Gun Voltage | V | 30-1000 |
| Initial Powder Feed | g/min. | 10-200 |
| Distance | mm | 50-300 |
| Gas Flow Rate | L/min. | 30-1000 |

FIG. 4 depicts particles 405 in a ceramic powder 400 in accordance with at least one embodiment described herein. At least a portion of the particles 205 may have a spherical shape with deep indentions 410 on opposite sides of the sphere. In other words, some ceramic particles 405 may have a donut shape 415. Without being bound to any particular theory, it is believed that in some embodiments, coatings formed from a ceramic powder 400 with particles 405 having a donut shape 415 may have improved morphology and porosity as compared to coatings formed with particles of other shapes. For example, coatings formed of particles 405 having a donut shape 415 may have fewer nodules and splats due to improved melting of the powder, decreased roughness, and decreased porosity, all of which contribute to improved on-wafer particle performance. In one embodiment, a first ceramic powder (e.g., first ceramic powder 315) used during a first phase of a plasma spray process has a typical spherical shape and a second ceramic powder (e.g., second ceramic powder 320) used during a second phase of the plasma spray process has a donut shape. In an example embodiment, a first ceramic powder used during a first deposition phase has a micron-scale size and is spherical, a second ceramic powder used during a second deposition phase is micron-scale size and is donut shaped, a third ceramic powder used during a third deposition phase is nano-scale size and is spherical, and a fourth ceramic powder used during a fourth deposition phase is nano-scale size and is donut shaped.

FIG. 5 illustrates one embodiment of a process 500 for forming a plasma sprayed ceramic coating over a chamber component or other article. One or more operations of the process 500 may be performed by a plasma spray system (e.g., plasma spray system 204 and/or 300) based on a plasma spray recipe. The plasma spray recipe may be loaded into the plasma spray system 204 and executed automatically in embodiments.

At block 505, a substrate is prepared for coating. The substrate may be a metal substrate such as aluminum, copper, magnesium, or another metal or a metal alloy. The substrate may also be a ceramic substrate, such as alumina, yttria, or another ceramic or a mixture of ceramics. Preparing the substrate may include shaping the substrate to a target form, grinding, blasting or roughening the substrate to provide a particular surface roughness and/or cleaning the substrate. In one embodiment, the substrate is roughened. This may activate the surface by increasing the free space energy and may strengthen mechanical bonding of the ceramic coating to the substrate.

At block 510, optimal initial powder characteristics for plasma spraying a ceramic coating are selected. In one embodiment, an optimal powder type and an optimal powder size distribution are selected for the initial powder. In one embodiment, ceramic powder having an average particle size of about 5-100 μm is selected. Some possible alternative average particle sizes for the ceramic powder include 50-100 μm, 60-100 μm, 70-100 μm, 80-100 μm, and 90-100 μm. In one embodiment, an optimized agglomerate powder size distribution is selected where 10% of agglomerate powder (D10) has a size of less than 10 μm, 50% of agglomerate powder (D50) has a size of 10-30 μm and 90% of agglomerate powder (D90) has a size of less than 55 μm for the initial powder.

Raw ceramic powders having specified compositions, purity and particle sizes are selected. The ceramic powder may be formed of any of the ceramic materials previously discussed for use in a ceramic coating. The raw ceramic powders may then be mixed. These raw ceramic powders may have a purity of 99.9% or greater in one embodiment. The raw ceramic powders may be mixed using, for example, ball milling.

After the ceramic powders are mixed, they may be calcinated at a specified calcination time and temperature. In one embodiment, a calcination temperature of approximately 1200-2000° C. (e.g., 1400° C. in one embodiment) and a calcination time of approximately 2-5 hours (e.g., 3 hours in one embodiment) is used. The spray dried granular particle size for the mixed powder may have a size distribution with an average diameter of approximately 5-100 μm in one embodiment, or any of the other aforementioned average diameters. One example average particle size is 30-50 μm. Optimal initial plasma spray parameters may also be selected. In one embodiment, optimizing plasma spray parameters includes, but is not limited to, setting a plasma gun power and a composition of spray carrier gas. In one embodiment, an initial powder feed rate is selected. In one embodiment, the initial powder feed rate is 20-100 g/min. In one embodiment, the initial powder feed rate is about 30-40 g/min.

At block 515, at least one surface of the article is coated according to the selected powder characteristics (e.g., initial average particle size) and plasma spray parameters (e.g., initial powder feed rate) to form a first layer of the ceramic coating. Coating the at least one surface of the article includes feeding the selected ceramic powder into the plasma spraying system at the selected powder feed rate. The first layer may then be formed using the selected powder feed rate and the selected ceramic powder. Plasma spraying techniques may melt materials (e.g., ceramic powders) and spray the melted materials onto the article using the selected parameters. In one embodiment, depositing the first layer comprises fully melting a first percentage of particles in the first ceramic powder. The first percentage of particles may be melted before the first percentage of particles in the first ceramic powder impact the at least one surface of the article and/or during impact of the first percentage of particles with the article. In one embodiment, the first layer of the plasma sprayed ceramic coating may have a thickness about 50 microns to about 9 mil (e.g., about 2-6 mil, 4-6 mil, 4-8 mil, etc.). In one embodiment, the first layer of the plasma sprayed ceramic coating has a thickness of about 200-650 microns. The first layer thickness may also be expressed as a percentage of total thickness (also referred to as final target thickness). In one embodiment, the first layer target thickness is anywhere from 20-99.9% of the total thickness.

The plasma spray process may be performed in multiple spray passes. For each pass, the angle of a plasma spray nozzle may change to maintain a relative angle to a surface that is being sprayed. For example, the plasma spray nozzle may be rotated to maintain an angle of approximately 45 degrees to approximately 90 degrees with the surface of the article being sprayed. Each pass used to generate the first layer may deposit a thickness of up to approximately 25 μm.

At block 520, a determination is made as to whether a target thickness for the first layer of the ceramic coating has been reached. The target thickness may be determined based on a known deposition rate for the selected powder at the selected powder feed rate and an amount of time that has passed since the deposition began. The process may include a target final thickness for the ceramic coating and may additionally include one or more additional target thicknesses for layers that make up the ceramic coating. The target final thickness may be anywhere from 50 microns to 10 mil. In one embodiment, the target final thickness is 1-10 mil. In one embodiment, the target final thickness is 8-10 mil. In one embodiment, the target final thickness is 50-200 microns greater than the target thickness for the first layer.

The layers may not be distinguishable from one another after deposition, but may be deposited during different phases of the deposition process. The first layer target thickness and each subsequent layer's target thickness may be defined as a percentage of the target final thickness in embodiments. For example, the first layer target thickness and/or subsequent target thickness may be 50%, 60%, 70%, 80%, 90%, etc. of the target final thickness for the ceramic coating. If the target thickness for the first layer is reached, the method continues to block 525. If the target thickness is not reached, the method returns to block 515 and additional plasma spraying is performed using the existing powder feed rate and/or powder.

At block 525, a determination is made as to whether a target final thickness for the ceramic coating has been reached. If the target final thickness has been reached, the method ends. If the target final thickness has not been reached, then the method continues to block 530.

At block 530, a new lower powder feed rate and/or a new powder having a smaller average particle size may be selected. If a ceramic powder with a lower average particle size is selected, the average particle size may be about 1-80 μm (but lower than the original average particle size) or may be a nanopowder (e.g., with an average particle size of about 1-500 nm). Some example average powder thickness ranges that may be used at block 530 are 1-2 μm, 1-3 μm, 1-4 μm, 1-5 μm, 1-10 μm, 1-20 μm, 1-30 μm, 1-40 μm, 1-50 μm, 1-60 μm and 1-70 μm. If a new lower powder feed rate is selected, then the powder feed rate may be some percentage of the original powder feed rate (e.g., 40-80% of the original powder feed rate). Additionally, or alternatively, a new powder having donut shaped particles may be selected (e.g., if the initial powder had a spherical shape).

The method may then return to block 515, and the article may be plasma sprayed to form a next layer of the ceramic coating using the newly selected powder feed rate and/or the newly selected powder. Plasma spraying the article to form the next layer may include feeding the selected ceramic powder (e.g., the first or initial ceramic powder, a second ceramic powder, or a subsequent ceramic powder) into the plasma spraying system at the selected powder feed rate (e.g., at the first or initial powder feed rate, a second powder feed rate, or a subsequent powder feed rate). The next layer may then be formed using the selected powder feed rate and the selected ceramic powder. In one embodiment, depositing the next layer comprises fully melting a second percentage of particles in the selected ceramic powder (e.g., first ceramic powder or second ceramic powder). The second percentage of particles may be fully melted before the second percentage of particles in the selected ceramic powder impact the at least one surface of the article and/or upon impact with the article. The second percentage of particles that are fully melted may be greater than the first percentage of particles that were fully melted at the deposition of the first layer due to the lower powder feed rate and/or the smaller average particle size. The second layer may have a thickness that is equal to or less than a thickness of the first layer. For example, the second layer may have a thickness that is 0.1-100% of the first thickness (e.g., 100%, 90%, 80%, 70%, 60%, 50%, 40%, 30%, 20% or 10% of the first thickness). In one embodiment, the second layer is produced using a few coating passes, and has a thickness of about 50-200 microns.

The process 500 may continue to loop through blocks 515, 520, 525 and 530 until a final target thickness is reached at block 525. With each iteration of block 530, a new lower powder feed rate may be selected (which may be lower than any previously selected powder feed rate), a new powder may be selected (which may have a smaller average powder size than any previously selected powder), or both a new lower powder feed rate and a new smaller powder size may be selected. At each iteration, a new layer of the ceramic coating is then formed by feeding a selected ceramic powder into the plasma spray system at a selected powder feed rate. Note that as the powder feed rate is reduced, the deposition rate of the ceramic coating is also reduced proportionally. In one embodiment, each successive layer is thinner than the preceding layer. In one embodiment, the ceramic coating has an average surface roughness (Ra) of about 60-120 micro-inches. In other embodiments, the ceramic coating has an average surface roughness of 60-70 micro-inches, 60-80 micro-inches, 60-90 micro-inches, 60-100 micro-inches, or 60-110 micro-inches.

By reducing the powder feed rate and/or the particle size of the powder for a second phase of the deposition process (and possibly further reducing the particle size of the powder and/or the particle feed rate during still further phases of the deposition process), a surface quality of the ceramic coating may be improved. This may reduce or eliminate loose particles on the ceramic coating, and may reduce or eliminate partially melted nodules. By reducing the particle size and/or by reducing the particle feed rate to deposit a top layer of the ceramic coating, the percentage of fully melted particles is increased. Both unmelted particles and partially melted nodules can cause contamination during processing. Additionally, the upper portion of the ceramic coating may have a higher density and lower porosity than it would have using a standard plasma spray process. Additionally, reducing the particle feed rate and/or the particle average size during the later and/or final phases of the deposition process may cause the ceramic coating to have a surface roughness that is approximately 20-25% lower (smoother) than a surface roughness of a plasma resistant ceramic coating deposited using a standard plasma spray process.

TABLE 2
Plasma Spray Coating Range

| Metric | Units | Standard | Embodiments |
|---|---|---|---|
| Partially Melted Surface Nodules | % | X | Y |
| Surface Roughness (Ra) | μ- | 150-350 | 60-150 |
| | inch | | |
| HCI Bubble Time | hr | X | Y |
| Breakdown Voltage | V/mil | X | Y |
| Porosity | % | 3-10% | 1-3% |

Table 2 illustrates measured coating characteristics achieved in embodiments of the present disclosure. Porosity may be measured as a fraction of the volume of voids over the total volume of the ceramic coating. In one embodiment, the porosity of the ceramic coating is approximately uniform throughout the ceramic coating. The approximately uniform porosity of the ceramic coating may be achieved by reducing the powder feed rate and/or the average particle size of the ceramic powder for an upper layer of the ceramic coating and/or by gradually reducing the powder feed rate and/or the average particle size in multiple steps or phases of the plasma spray deposition.

As shown, the ceramic coating that results from a standard plasma spray process typically has an average surface roughness of about 150-350μ-inch and a porosity of about 3-10% at a surface of the ceramic coating. In contrast, the ceramic coating that results when embodiments of the present disclosure are applied to deposit the ceramic coating have lower average surface roughness and lower porosity at the surface of the ceramic coating. In one embodiment, the average surface roughness of the ceramic coating applied as discussed herein is 60-150μ-inch. In one embodiment, the average surface roughness is 60-140μ-inch. In one embodiment, the average surface roughness is 60-130μ-inch. In one embodiment, the average surface roughness is 60-120μ-inch. In one embodiment, the average surface roughness is 60-110μ-inch. In one embodiment, the average surface roughness is 60-100μ-inch. In one embodiment, the average surface roughness is 60-90μ-inch. In one embodiment, the average surface roughness is 60-80μ-inch. In one embodiment, the average surface roughness is 60-70μ-inch.

In one embodiment, the porosity at the surface of the ceramic coating is 1-3% when process 500 is performed. In one embodiment, the porosity at the surface of the ceramic coating is 1-2.8%. In one embodiment, the porosity at the surface of the ceramic coating is 1-2.6%. In one embodiment, the porosity at the surface of the ceramic coating is 1-2.5%. In one embodiment, the porosity at the surface of the ceramic coating is 1-2.4%. In one embodiment, the porosity at the surface of the ceramic coating is 1-2.2%. In one embodiment, the porosity at the surface of the ceramic coating is 1-2%. In one embodiment, the porosity at the surface of the ceramic coating is 1-1.8%. In one embodiment, the porosity at the surface of the ceramic coating is 1-1.6%. In one embodiment, the porosity at the surface of the ceramic coating is 1-1.5%. In one embodiment, the porosity at the surface of the ceramic coating is 1-1.4%. In one embodiment, the porosity at the surface of the ceramic coating is 1-1.2%.

The preceding description sets forth numerous specific details such as examples of specific systems, components, methods, and so forth, in order to provide a good understanding of several embodiments of the present disclosure. It will be apparent to one skilled in the art, however, that at least some embodiments of the present disclosure may be practiced without these specific details. In other instances, well-known components or methods are not described in detail or are presented in simple block diagram format in order to avoid unnecessarily obscuring the present disclosure. Thus, the specific details set forth are merely exemplary. Particular implementations may vary from these exemplary details and still be contemplated to be within the scope of the present disclosure.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.”

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

It is to be understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. A method, comprising:
feeding a first ceramic powder into a plasma spraying system at a first powder feed rate of about 10-200 grams per minute;
depositing a first layer of a ceramic coating on at least one surface of an article in a first phase of a plasma spray process by the plasma spray system using the first powder feed rate;
subsequently feeding at least one of the first ceramic powder or a second ceramic powder into the plasma spraying system at a second powder feed rate that is lower than the first powder feed rate, wherein the second powder feed rate is 10-90% lower than the first powder feed rate; and
depositing a second layer of the ceramic coating over the first layer on the at least one surface of the article in a second phase of the plasma spray process by the plasma spray system using the second powder feed rate, wherein the first powder feed rate causes a higher deposition rate than the second powder feed rate, and wherein the second powder feed rate causes a surface of the ceramic coating to have a first quantity of surface particles, a first average surface roughness and a first porosity that are lower than a respective second quantity of surface particles, a second average surface roughness and a second porosity that would be generated with use of the first powder feed rate for the second layer.

2. The method of claim 1, wherein the article is a chamber component for a processing chamber, the article comprising at least one of a metal or a sintered ceramic.

3. The method of claim 1, wherein the ceramic coating consists essentially of at least one of Y₂O₃, Al₂O₃, Er₂O₃, Gd₂O₃, YF₃, Nd₂O₃, Er₄Al₂O₉, Er₃Al₅O₁₂, ErAlO₃, Gd₄Al₂O₉, GdAlO₃, Nd₃Al₅O₁₂, Nd₄Al₂O₉, NdAlO₃, YAlO₃, Y₄Al₂O₉, Y₃Al₅O₁₂ (YAG), a solid solution of Y₂O₃—ZrO₂, a ceramic compound comprising Y₄Al₂O₉ and a solid-solution of Y₂O₃—ZrO₂, a ceramic compound comprising Y₂O₃ and YF₃, or a ceramic compound comprising Y₂O₃, Er₂O₃, ZrO₂, Gd₂O₃ and SiO₂.

4. The method of claim 1, wherein the ceramic coating has an approximately uniform porosity of about 1-3%, wherein the approximately uniform porosity is achieved based on use of the first powder feed rate for the first layer and the second powder feed rate for the second layer.

5. The method of claim 1, wherein the first layer has a first thickness of about 2-6 mil, and wherein the second layer has a second thickness that is equal to or less than the first thickness.

6. The method of claim 1, further comprising:
feeding at least the first ceramic powder into the plasma spraying system at a third powder feed rate that is lower than the second powder feed rate; and
depositing a third layer of the ceramic coating on the at least one surface of the article in the plasma spray process by the plasma spray system.

7. The method of claim 1, wherein the first ceramic powder has a first average particle size, and wherein the second ceramic powder has a second average particle size that is lower than the first average particle size.

8. The method of claim 7, wherein the first average particle size is about 5-100 μm in diameter, and wherein the second average particle size is about 1-80 μm in diameter.

9. The method of claim 1, wherein depositing the first layer comprises melting a first percentage of particles in the first ceramic powder before the first percentage of the particles in the first ceramic powder impact the at least one surface of the article, wherein depositing the second layer comprises melting a second percentage of the particles in the first ceramic powder before the second percentage of the particles in the first ceramic powder impact the at least one surface of the article, and wherein the second percentage of particles is greater than the first percentage of particles.

10. The method of claim 1, wherein the average surface roughness of the ceramic coating is about 60-120 micro-inches.

11. The method of claim 1, wherein the second powder feed rate is about 50-80% of the first powder feed rate.

12. A method comprising:
feeding a first ceramic powder into a plasma spraying system at a first powder feed rate, wherein the first ceramic powder has a first average particle size;
depositing a first layer of a ceramic coating on at least one surface of an article in a plasma spray process by the plasma spray system using the first ceramic powder;
feeding a second ceramic powder into the plasma spraying system at the first powder feed rate or at a second powder feed rate that is lower than the first powder feed rate, wherein the second ceramic powder has a second average particle size that is lower than the first average particle size; and
depositing a second layer of the ceramic coating on the at least one surface of the article in the plasma spray process by the plasma spray system using the second ceramic powder.

13. The method of claim 12, wherein the first average particle size is about 5-100 μm in diameter, and wherein the second average particle size is about 1-80 μm in diameter.

14. The method of claim 12, wherein the ceramic coating consists essentially of at least one of Y₂O₃, Al₂O₃, Er₂O₃, Gd₂O₃, YF₃, Nd₂O₃, Er₄Al₂O₉, Er₃Al₅O₁₂, ErAlO₃, Gd₄Al₂O₉, GdAlO₃, Nd₃Al₅O₁₂, Nd₄Al₂O₉, NdAlO₃, YAlO₃, Y₄Al₂O₉, Y₃Al₅O₁₂ (YAG), a solid solution of Y₂O₃—ZrO₂, a ceramic compound comprising Y₄Al₂O₉ and a solid-solution of Y₂O₃—ZrO₂, a ceramic compound comprising Y₂O₃ and YF₃, or a ceramic compound comprising Y₂O₃, Er₂O₃, ZrO₂, Gd₂O₃ and SiO₂.

15. The method of claim 12, wherein the ceramic coating has an approximately uniform porosity of about 1-3%.

16. The method of claim 12, wherein the first layer has a first thickness of about 2-6 mil, and wherein the second layer has a second thickness that is equal to or less than the first thickness.

17. The method of claim 12, further comprising:
feeding a third ceramic powder into the plasma spraying system at the first powder feed rate, wherein the third ceramic powder has a third average particle size that is lower than the second average particle size; and
depositing a third layer of the ceramic coating on the at least one surface of the article in the plasma spray process by the plasma spray system.

18. The method of claim 12, wherein depositing the first layer comprises melting a first percentage of particles in the first ceramic powder before the first percentage of the particles in the first ceramic powder impact the at least one surface of the article, wherein depositing the second layer comprises melting a second percentage of particles in the second ceramic powder before the second percentage of the particles in the second ceramic powder impact that at least one surface of the article, and wherein the second percentage of particles is greater than the first percentage of particles.

19. The method of claim 12, wherein the first layer has a first thickness of about 2-6 mil, and wherein the second layer has a second thickness that is equal to or less than the first thickness.

20. A chamber component for a processing chamber, the chamber component having a ceramic coating on at least one surface, the ceramic coating having been formed by a process comprising:
feeding a first ceramic powder into a plasma spraying system at a first powder feed rate;
depositing a first layer of the ceramic coating on the at least one surface of the chamber component in a plasma spray process by the plasma spray system using the first powder feed rate;
feeding at least one of the first ceramic powder or a second ceramic powder into the plasma spraying system at a second powder feed rate that is lower than the first powder feed rate; and
depositing a second layer of the ceramic coating on the at least one surface of the chamber component in the plasma spray process by the plasma spray system using the second powder feed rate.
